(19) United States
(12) Patent Application Publication
(10) Pub. No.: US 2026/0007085 A1
(43) Pub. Date: Jan. 1, 2026

(54) MEMORY CELL

(71) Applicant: STMicroelectronics International N.V., Geneva (CH)

(72) Inventors: Valentin BACQUIE, Grenoble (FR); Sarah RUBECK, Arvillard (FR)

(73) Assignee: STMicroelectronics International N.V., Geneva (CH)

(21) Appl. No.: 19/242,638

(22) Filed: Jun. 18, 2025

(30) Foreign Application Priority Data
Jun. 28, 2024 (FR) FR2407027

(51) Int. Cl. H10N 70/00; H10B 63/00; H10B 63/10

(52) U.S. Cl. CPC H10N 70/8613; H10B 63/10; H10B 63/30; H10N 70/023

(57) ABSTRACT

An electronic device includes a plurality of memory cells organized in an array, forming rows and columns. Each memory cell includes a stack of a resistive heating element, of a layer made of a phase-change material, of an upper electrode, and of a masking layer. The layer made of the phase-change material, the upper electrode, and the masking layer are common to the memory cells of a same row and are covered by an encapsulation layer. The encapsulation layer covers an upper surface of the masking layer and side flanks of the masking layer, of the upper electrode, and of the layer made of the phase-change material. The masking layer has a thickness lower than 15 nm.

### CROSS-REFERENCE TO RELATED APPLICATIONS

This application claims the priority benefit of French patent application number FR2407027, filed on Jun. 28, 2024, entitled “Cellule mémoire” which is hereby incorporated by reference to the maximum extent allowable by law.

### BACKGROUND

### Technical Field

The present disclosure generally concerns the field of electronic devices and more particularly the field of electronic chips including a memory circuit, based on a phase-change material, and their manufacturing methods.

### Description of the Related Art

A phase-change material is a material having the ability to change phase under the effect of heat, and more particularly to switch between a crystalline state and an amorphous state, which is more highly resistive than the crystalline state. This phenomenon is used to define two memory states, for example 0 and 1, differentiated by the resistance measured through the phase-change material.

There exists a need to improve electronic chips including a memory circuit based on a phase-change material.

### BRIEF SUMMARY

For this purpose, an embodiment provides an electronic device including a plurality of memory cells organized in an array, forming rows and columns,
each memory cell including a stack of a resistive heating element, of a layer made of a phase-change material, of an upper electrode, and of a masking layer,
the layer made of the phase-change material, the upper electrode, and the masking layer being common to the memory cells of a same row and covered by an encapsulation layer, the encapsulation layer covering an upper surface of the masking layer and side flanks of the masking layer, of the upper electrode, and of the layer made of the phase-change material,
wherein the masking layer has a thickness lower than 15 nm.

According to an embodiment, the masking layer has a thickness in the order of 5 nm.

According to an embodiment, the masking layer is made of silicon nitride.

According to an embodiment, the masking layer and the encapsulation layer are made of a silicon nitride having the same stoichiometry.

According to an embodiment, the masking layer and encapsulation layer have a density lower than 2.2 g/cm3.

According to an embodiment, the masking layer or the encapsulation layer is made of a stack of a plurality of sub-layers.

According to an embodiment, the masking layer and the encapsulation layer are crossed by a conductive via, the conductive via being in contact with the upper electrode.

Another embodiment provides a method of manufacturing an electronic device including a plurality of memory cells organized in an array, forming rows and columns, the method including the steps of:
a) forming of a stack of a resistive element, of a layer made of a phase-change material, and of an upper electrode;
b) deposition of a masking layer on the above-mentioned stack with a thickness lower than 20 nm;
c) etching of the masking layer and of the stack so as to create, in the layer made of the phase-change material, the upper electrode, and the masking layer, lines; and
d) deposition of an encapsulation layer covering an upper surface of the masking layer and side flanks of the masking layer, of the upper electrode, and of the layer made of the phase-change material.

According to an embodiment, the masking layer is, at step b), deposited according to a conformal deposition method.

According to an embodiment, the masking layer is, at step b), deposited according to a nanometric deposition method.

According to an embodiment, the masking layer is, at step b), deposited according to a plasma-enhanced chemical vapor deposition method, this method being pulsed.

According to an embodiment, during step b), the plasma is activated by pulses having a power in the range from 80 W to 200 W.

According to an embodiment, step b) has a duration longer than 30 seconds.

According to an embodiment, during step b), the pulses of the plasma have a frequency in the range from 800 Hz to 1,500 Hz.

According to an embodiment, the method includes, between steps b) and c), a step of thermal treatment of the masking layer.

According to an embodiment, the encapsulation layer and the masking layer are deposited according to the same deposition method.

Another embodiment provides a method of using an electronic device such as defined hereabove, including the application of a current in the resistive heating element of one of the memory cells, which results in a change of crystalline phase of the layer made of the phase-change material of the memory cell, allowing the storage of a data bit.

According to an embodiment, a device includes a row of memory cells including a stack of a layer of phase change material, an upper electrode, and a masking layer. The layer of phase change material, the upper electrode, and the masking layer being common to all of the memory cells of the row. Each memory cell of the stack includes a respective resistive element coupled to the stack. The device includes an encapsulation layer covering an upper surface of the masking layer and side flanks of the masking layer, the upper electrode, and the layer of phase-change material, wherein each memory cell of the row includes a respective resistive heating element.

According to an embodiment, the masking layer has a thickness lower than 15 nm.

According to an embodiment, the masking layer or the encapsulation layer is made of a stack of a plurality of sub-layers.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an example of an electronic device;

FIG. 2A and FIG. 2B are cross-section views, partial and simplified, of the device of FIG. 1;

FIG. 3, FIG. 4, FIG. 5, and FIG. 6 are cross-section views, partial and simplified, illustrating steps of an example of a method of manufacturing another electronic device according to an embodiment.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10% or 10°, preferably of plus or minus 5% or 5°.

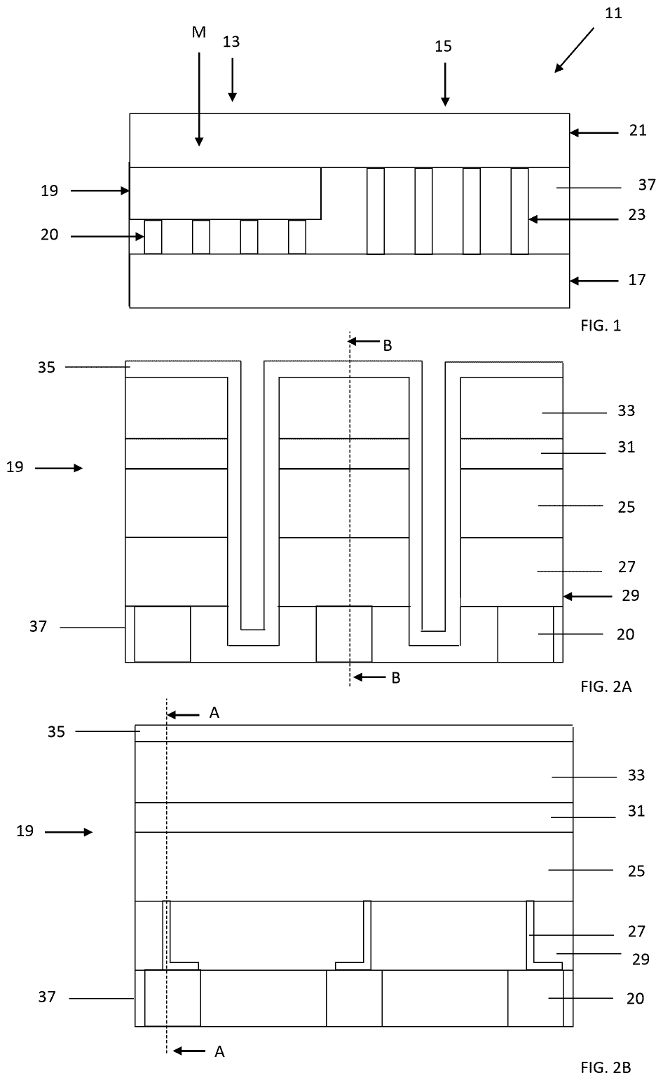

FIG. 1 is a cross-section view, partial and simplified, of an example of an electronic device including a memory element.

Device 11 is for example an electronic chip.

Device 11 includes, for example, a memory circuit 13 and a logic circuit 15. Memory circuit 13 and logic circuit 15 are for example formed on top and/or inside of a semiconductor substrate 17. As an example, substrate 17 is made of silicon or based on silicon.

As an example, device 11 includes, in each of memory circuit 13 and logic circuit 15, a plurality of transistors, not shown, formed inside and on top of substrate 17. The transistors are, for example, arranged in an array including rows and columns.

In the memory circuit, the transistors are, for example, topped with a memory element 19 including a plurality of memory cells M, each transistor being associated with a memory cell M. As an example, in memory circuit 13, the transistors are transistors of selection of the memory cell M. As an example, substrate 17 is coupled to memory element 19 via conductive vias 20. As an example, each via 20 couples a selection transistor to an associated memory cell M. As an example, the conductive vias 20 are for example made of a metallic material. The conductive vias 20 are for example made of copper, of cobalt, or of tungsten.

Memory cells M are phase-change memory cells, that is, including a layer made of a phase-change material.

In memory circuit 13, the memory cells M of memory element 19 are organized, in top view, in an array of rows and columns. It is respectively spoken of word lines and of bit lines. As an example, each memory cell M is located at the intersection of a bit line and of a word line. As an example, the array formed by memory cells M is identical to the array formed by the transistors.

As an example, the device includes, in memory circuit 13 and logic circuit 15, an interconnection stack 21. As an example, the interconnection stack is formed on the upper surface of memory element 19. In this example, memory element 19 is thus formed between interconnection stack 21 and substrate 17. Interconnection stack 21 for example covers the entire surface of substrate 17.

Interconnection stack 21 is for example formed of a succession of levels, each level including a succession of insulating layers. As an example, interconnection stack 21 has a thickness in the range from 300 nm to 800 nm, for example from 400 nm to 700 nm, for example of the order of 500 nm. Each level includes, for example, conductive vias and conductive tracks crossing said level. The conductive vias and tracks are for example made of a metallic material, for example of copper or of tungsten.

As an example, substrate 17, and more specifically the transistors arranged in substrate 17, are electrically coupled to interconnection stack 21 via conductive vias 23. Contactor vias 23 are for example in contact, via their lower surfaces, with the transistors arranged in substrate 17 and via their upper faces, with interconnection stack 21. For example, conductive vias 23 are made of a metallic material. Conductive vias 23 are for example made of copper, of cobalt, or of tungsten.

Conductive vias 23 thus extend from the upper surface of substrate 17 to the lower surface of interconnection stack 21. The height of conductive vias 23 is then identical to the thickness of memory element 19, to which the height of the vias 20 is added.

As an example, vias 23 cross, between interconnection stack 21 and substrate 17, an insulating layer 37. Further, layer 37 is, for example, also crossed by vias 20.

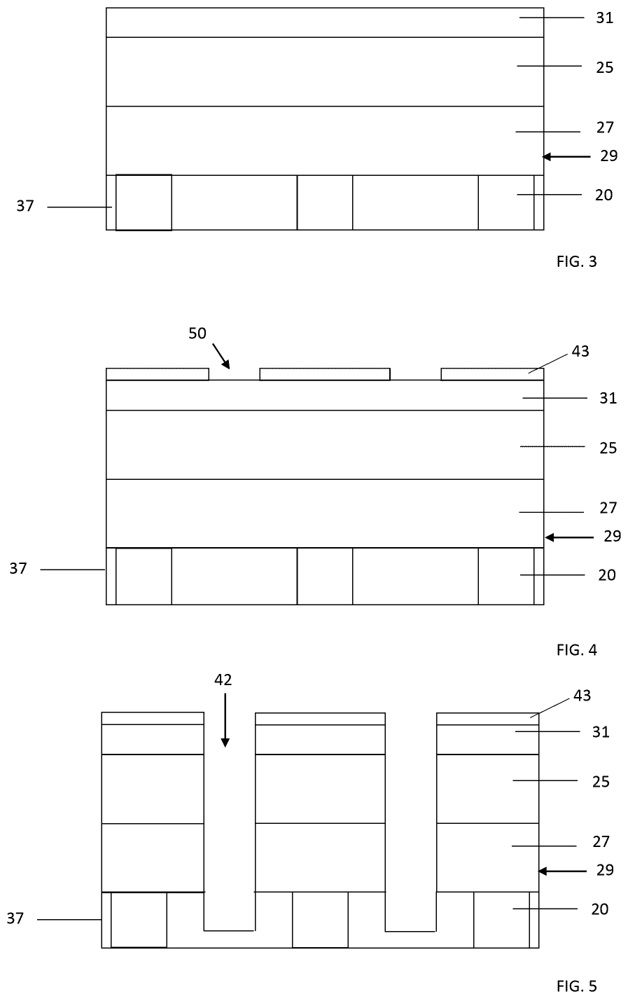

FIG. 2A and FIG. 2B are cross-section views, partial and simplified, of an example of the memory element 19 of FIG. 1. More particularly, FIG. 2A is a cross-section view along the cross-section plane AA of FIG. 2B and FIG. 2B is a view along the cross-section plane BB of FIG. 2A.

More particularly, in FIG. 2A, three memory cells M of memory element 19 are at least partially shown. As an example, the memory cells M shown in FIG. 2A are memory cells M of a same word line and correspond to three memory cells M of different bit lines.

Each cell M includes a layer 25 made of a phase-change material, for example a chalcogenide material, for example an alloy of germanium, antimony, and tellurium (GeSbTe) known as GST. Layer 25 has, for example, a thickness in the range from 30 nm to 100 nm, for example in the order of 50 nm. The memory cells M of the same bit line for example include a common layer 25. Thus, device 11 includes, in memory element 19, for example, as many layers 25 as there are bit lines. Each layer 25 thus extends in the bit line direction.

In each memory cell M, the phase-change material is controlled by a metallic resistive heating element 27 located under the phase-change material. Element 27 is for example in contact, by its upper surface, with the lower surface of layer 25. Element 27 is for example laterally surrounded by a layer made of a thermal insulator 29. For example, each element 27 has an “L” shape in the cross-section plane of FIG. 2B. As an example, element 27 is made of tantalum nitride or of titanium silicon nitride. As an example, layer 29 is made of silicon carbonitride, of silicon nitride, or of silicon oxide. As an example, heating elements 27 are in contact with vias 20. As an example, each heating element 27 for example has a height in the range from 30 nm to 100 nm, for example in the order of 60 nm.

Layer 25 is topped with a layer 31, for example made of a conductive material, for example made of a metallic material. More specifically, the upper surface of each layer 25 is for example at least partially covered, for example entirely covered, with a layer 31. Each layer 31 preferably extends, in the bit line direction, over the entire length of layer 25. Layer 31 is for example made of titanium nitride. As an example, layer 31 has a thickness in the range from 10 nm to 50 nm, for example in the order of 20 nm.

For example, in each memory cell M, metal element 27 and layer 31 respectively form a lower electrode and an upper electrode of memory cell M, and more specifically electrodes of the variable-resistance resistive element formed by the layer 25 made of the phase-change material. The memory cells M of a same bit line are topped with the same layer 31. In other words, the upper electrodes 31 of the memory cells M of a same bit line are interconnected.

Layer 31 is, for example, topped with a masking layer 33, for example made of an insulating material, for example a dielectric material. Masking layer 33 is for example made of a nitride, for example of silicon nitride. The upper surface of each layer 31 is for example at least partially covered, for example fully covered, with a layer 33. Each layer 33 preferably extends, in the bit line direction, along the entire length of layer 31. As an example, layer 33 has a thickness in the order of 25 nm.

Layer 33 is for example deposited by a plasma-enhanced chemical vapor deposition (PECVD) method. The PECVD deposition method consists in the generation of a plasma which, reacting with a precursor gas, produces one or a plurality of new chemical species which will interact with a substrate by bonding thereto to form a deposit. During the deposition of layer 33, the precursor gas is silane (SiH₄), ammonia (NH₃), nitrogen (N₂) or a combination of two or more of these elements. During this step, the power of the plasma is in the range from 400 W to 600 W, for example in the order of 500 W. The duration of the deposition of layer 33 is for example in the range from 5 seconds to 6 seconds.

Each memory cell M is for example covered by an encapsulation layer 35 protecting, for example, the layer 25 made of the phase-change material from oxidation. As an example, encapsulation layer 35 covers the upper surface of layer 33 and the flanks of layers 33, 31, 25, and 29. Encapsulation layer 35 is for example made of a dielectric material. Encapsulation layer 35 is for example made of a nitride, for example of silicon nitride. Encapsulation layer 35 for example has a thickness in the range from 20 nm to 50 nm, for example in the order of 33 nm.

Layers 35 and 33 are deposited by different deposition methods. As an example, layers 35 and 33 are made of the same material, for example of silicon nitride, but have different stoichiometries, that is, the nitrogen and silicon contents in the two layers 33 and 35 are different.

Memory cells M are, for example, each electrically coupled to the transistor which is associated therewith by via 20. Vias 20 for example run through insulating layer 37. Memory cells M thus rest on the upper surface of layer 37 and of vias 20.

In the example of FIGS. 2A and 2B, the thickness of memory cells M thus corresponds to the sum of the thicknesses of layers 35, 33, 31, 25, and 29. The height of conductive vias 23 shown in FIG. 1 is then directly related to the thickness of the above-mentioned layers.

In the example of FIGS. 1 and 2, vias 23 for example have a height greater than or equal to 250 nm. Now, in a logic circuit including such vias, the greater the height of the vias, the greater the resistance of the vias and the lower the performance of logic circuit 15.

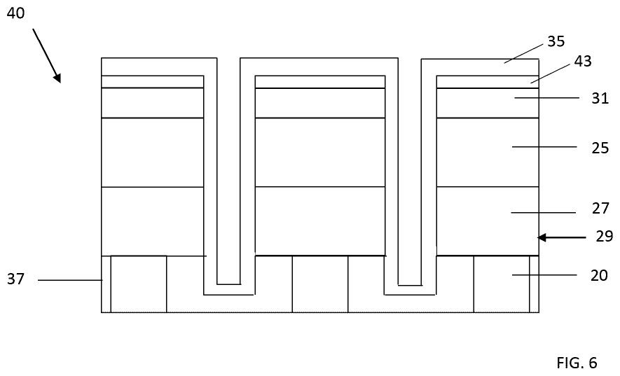

FIG. 3, FIG. 4, FIG. 5, and FIG. 6 are cross-section views, partial and simplified, illustrating steps of an example of a method of manufacturing an electronic device according to an embodiment.

More particularly, FIGS. 3 to 6 illustrate steps of a method of manufacturing a device 40 different from the device 11 illustrated in FIGS. 1 and 2, in that masking layer 33 is replaced with a masking layer 43 having a thickness lower than 15 nm.

FIG. 3 illustrates an initial structure including, on the upper surface of insulating layer 37 crossed by vias 20, insulating layer 29 including a plurality of heating elements 27. The initial structure illustrated in FIG. 3 further includes, on top of and in contact with the upper surface of layer 29 and of elements 27, the layer 25 made of the phase-change material. Further, the initial structure includes, on top of and in contact with the upper surface of layer 25, conductive layer 31.

In this structure, layers 29, 25, and 31 extend, for example, over the entire surface of layer 37.

FIG. 4 illustrates a structure obtained at the end of a step of deposition of masking layer 43 on the upper surface of the structure shown in FIG. 3.

Masking layer 43 is, for example, made of an insulating material, for example of a dielectric material. Masking layer 43 is for example made of a nitride, for example of silicon nitride.

During this step, layer 43 is deposited by a nanometric deposition method. Layer 43 is for example deposited by a pulsed PECVD deposition method. This deposition method is similar to the PECVD deposition method, except that the power of the plasma is not constant over the entire duration of the deposition. The power of the plasma is, in this method, pulsed, that is, it follows pulses. In this method, the power of the plasma alternates between a high power and a low power. As an example, the high power is in the range from 80 W to 200 W, for example in the order of 107 W. As an example, the low power is substantially zero. During the deposition of layer 43, the precursor gas is trisilylamine, ammonia (NH₃), nitrogen (N₂), or a combination of two or more of these elements.

The pulse frequency is, in this method, in the range from 800 Hz to 1,500 Hz, for example in the order of 1,000 Hz. As an example, over the duration of the deposition of layer 43, the plasma is ignited, for example between 5% and 20% of the time, for example approximately 10% of the time. The deposition of layer 43 has a duration longer than 30 seconds, for example in the range from 60 seconds to 120 seconds, and is, for example, in the order of 91 seconds. During this step, layer 43 is deposited with a thickness lower than 15 nm, for example in the order of 11 nm.

As an example, an 11-nm deposition of layer 43 is performed when:
the power of the plasma is, in its high value, 107 W;
the pulse frequency is 1,000 Hz;
the plasma is activated for 10% of the time; and
the duration of the deposition is 91 seconds.

As an example, at the end of the deposition of layer 43, the latter undergoes a treatment step enabling to densify layer 43 with nitrogen. In other words, layer 43 undergoes, at the end of its deposition, a step enabling it to further charge with nitrogen. As an example, this treatment consists in an exposure of the surface of layer 43 to a nitrogen and helium plasma.

The sequence of a deposition according to the pulsed PECVD method followed by a treatment step corresponds to a pulsed PECVD deposition cycle.

As a variant, layer 43 is deposited by an atomic layer deposition (ALD) method.

At the end of the step of deposition of layer 43 over the entire upper surface of layer 31, layer 43 is locally etched to create, in layer 43, through openings extending all the way to the surface of layer 31.

FIG. 5 illustrates a structure obtained at the end of a step of forming of trenches 42, in the structure illustrated in FIG. 4, by etching through masking layer 43. More particularly, during this step, the forming of trenches 42 is performed while masking layer 43 plays the role of an etch mask.

As an example, trenches 42 are formed from the upper surface of layer 31 in the stack of memory cells M to reach insulating layer 37. As an example, the etching is stopped when trenches 42 emerge into insulating layer 37.

During this step, the forming of trenches 42 enables to form the bit lines.

At the end of this step, layer 43 has a decreased thickness as compared with what has been described in relation with FIG. 4. Layer 43 indeed has, at the end of this step, a thickness lower than 10 nm, for example lower than 7 nm, for example in the order of 5 nm.

FIG. 6 illustrates a structure obtained at the end of a step of deposition of an encapsulation layer 35 on the upper surface of the structure shown in FIG. 5, so as to form device 40.

More particularly, during this step, layer 35 is deposited on the upper surface of layer 43 and in trenches 42, on the side flanks of the stack of layers 43, 31, 25, and 29. As an example, layer 35 is further deposited in the bottom of the trenches on the upper surface of layer 37.

As an example, the method of depositing layer 35 is similar, for example identical, to the method of depositing layer 43 illustrated in relation with FIG. 4.

Layer 35 is for example deposited according to a conformal deposition method. As an example, layer 35 is deposited according to a pulsed PECVD deposition method similarly to what has been described for layer 43. As an example, the deposition of layer 35 includes a plurality of pulsed PECVD deposition cycles. As an example, the deposition of layer 35 includes three pulsed PECVD deposition cycles.

As an example, layer 35 and layer 43 have, at the end of this step, the same composition. As an example, layers 43 and 35 have identical stoichiometries, that is, the nitrogen content and the silicon content in both layers 43 and 35 are identical. An advantage is that this enables to simplify the etching. It is indeed simpler to have a single type of layer to be etched, rather than a bi-material. This enables in particular to avoid or to limit double-slope problems linked to the implementation of distinct etch steps, or the use of different chemical solutions to perform the etching operations.

According to an aspect of the described embodiments, the silicon nitride of layers 35 and 43 has a density lower than 2.2, for example lower than 2.15. The density here corresponds to the density of the material expressed in g/cm³, divided by a reference density here equal to 1 g/cm³. Layers 35 and 43 thus have a density lower than 2.2 g/cm³, for example lower than 2.15 g/cm³.

According to an aspect of the described embodiments, layers 35 and 43 may each be formed of a plurality of sub-layers and correspond to a stack of a plurality of silicon nitride sub-layers formed during successive deposition cycles.

At the end of this step, layers 35 and 43 are for example etched on the side of the upper surface of each memory cell M. During this step, a portion of the upper surface of layer 31 is exposed and a conductive via, not shown, is formed therein in contact with layer 31. During this step, layers 43 and 35 are for example locally removed.

Many applications are likely to benefit from the advantages offered by electronic device 11, which device may thus be integrated in various types of components.

As an example, device 11 may be integrated in a component intended for the automotive industry. The electrification of motor vehicles entails a strong increase in the number of electronic components present in vehicles. The component includes, for example, thyristors, rectifiers, transient voltage suppression diodes, modules, etc., intended to be incorporated in said vehicles. Further, driving assistance and driving automation cause an increase in the number of electronic components in vehicles. The component for example includes transient voltage suppression diodes, an electrostatic discharge protection, and common-mode filters enabling to protect the component against electrical hazards.

As an example, device 11 may be integrated in a component intended for the industry. In particular, the component is used, for example, for the development of green energies or for the electrification of infrastructures, such as charging stations or solar energy collection. The component may also be used in the field of the Internet of Things or in the field of smart homes. The component is for example intended to be implemented in circuits for powering equipment, for example including 800-V or 1,200-V thyristors, ultrafast 1,200-V silicon carbide diodes, transient voltage suppression diodes, and electrostatic discharge protection. The component may also be used for the implementation of cloud computing systems, of 5G radio frequency communication networks, of data centers, and of servers. The component for example includes wide-bandgap materials.

As an example, device 11 may be integrated in a component intended to be used in personal electronics, for example in order to increase a volume of information exchanged by radio frequency communication, in 5G communication systems, or more generally in any connected component. The component is, for example, a cell phone, or smartphone, or forms part of an Internet of Things network. The component is for example connected by 5G, WiFi, or broadband communication. The component for example includes high-speed interfaces, for example with an advanced filtering and an electrostatic discharge protection.

As an example, device 11 may be integrated in a component intended to be used in communications equipment, or in computers and peripherals. The component is for example used in 5G infrastructures and dedicated data centers. The component for example includes silicon carbide diodes, Schottky power transistors, electrostatic discharge protections, and transient voltage suppression diodes. The component may also be used in satellites for example including integrated passive components for radio frequency applications.

An advantage of the present embodiment is that it enables to decrease the thickness of layer 43, and thus to decrease the thickness of memory element 19.

Another advantage of the present embodiment is that it enables to decrease the distance between substrate 17 and interconnection stack 21, and the height of vias 23 in the logic circuit of device 40. This generates a decrease in the resistance of vias 23. The thickness decrease of layer 33 further decreases the size (and thus the resistance) of the vias which connect the memory elements to the first metal level. This enables to improve the performance of the memory circuit.

Another advantage of the present embodiment is that it enables to decrease the depth of trenches 42 and thus to improve the filling of the trenches in a step subsequent to the step illustrated in FIG. 6. Indeed, the smaller the ratio of the width to the depth of a trench, the more difficult its filling will be, which may generate the forming of a void or closed space, at the center of the trenches, including no filling material. The present embodiment further enables to decrease risks of forming of this void.

While those skilled in the art would tend to provide an encapsulation layer 35 with a relatively high density, typically at least 2.4, in order to increase the stability of the layer, the resistance of the encapsulation layer to wet and dry etching, and to provide a better barrier to hydrogen and oxygen, still another advantage of the present embodiment is that the density lower than 2.2 of layers 35 and 43 enables to provide each memory cell M with a better temperature stability and thus a better manufacturing yield and a better reliability.

Various embodiments and variants have been described. Those skilled in the art will understand that certain features of these various embodiments and variants may be combined, and other variants will occur to those skilled in the art.

In particular, although embodiments have been described in which memory cells M are formed between interconnection stack 21 and vias 20, the embodiments are not limited to this particular case. As a variant, memory cells M may be formed above interconnection stack 21.

Finally, the practical implementation of the described embodiments and variants is within the abilities of those skilled in the art based on the functional indications given hereabove.

In one embodiment, an electronic device (40) includes a plurality of memory cells (M) organized in an array, forming rows and columns, each memory cell (M) including a stack of a resistive heating element (27), of a layer made of a phase-change material (25), of an upper electrode (31), and of a masking layer (43), the layer made of the phase-change material (25), the upper electrode (31), and the masking layer (43) being common to the memory cells of a same row and covered by an encapsulation layer (35), the encapsulation layer (35) covering an upper surface of the masking layer (43) and side flanks of the masking layer (43), of the upper electrode (31), and of the layer made of the phase-change material (25), wherein the masking layer (43) has a thickness lower than 15 nm.

In one embodiment, the masking layer (43) has a thickness in the order of 5 nm.

In one embodiment, the masking layer (43) is made of silicon nitride.

In one embodiment, the masking layer (43) and the encapsulation layer (35) are made of a silicon nitride having the same stoichiometry.

In one embodiment, the masking layer (43) and the encapsulation layer (35) have a density lower than 2.2 g/cm³.

In one embodiment, the masking layer (43) or the encapsulation layer (35) is made of a stack of a plurality of sub-layers.

In one embodiment, the masking layer (43) and the encapsulation layer (35) are crossed by a conductive via, the conductive via being in contact with the upper electrode (31).

In one embodiment, a method of manufacturing an electronic device (40) includes a plurality of memory cells (M) organized in an array, forming rows and columns, the method including the steps of: a) forming of a stack of a resistive element, of a layer made of a phase-change material (25), and of an upper electrode (31); b) deposition of a masking layer on the above-mentioned stack with a thickness lower than 20 nm; c) etching of the masking layer (43) and of the stack so as to create, in the layer made of the phase-change material (25), the upper electrode (31), and the masking layer (43), lines; and d) deposition of an encapsulation layer (35) covering an upper surface of the masking layer (43) and side flanks of the masking layer (43), of the upper electrode (31), and of the layer made of the phase-change material (25).

In one embodiment, the masking layer (43) is, at step b), deposited according to a conformal deposition method.

In one embodiment, the masking layer (43) is, at step b), deposited according to a nanometric deposition method.

In one embodiment, the masking layer (43) is, at step b), deposited according to a plasma-enhanced chemical vapor deposition method, this method being pulsed.

In one embodiment, during step b), the plasma is activated by pulses having a power in the range from 80 W to 200 W.

In one embodiment, step b) has a duration longer than 30 seconds.

In one embodiment, during step b), the pulses of the plasma have a frequency in the range from 800 Hz to 1,500 Hz.

In one embodiment, the method includes, between steps b) and c), a step of thermal treatment of the masking layer (25).

In one embodiment, the encapsulation layer (35) and the masking layer (43) are deposited according to the same deposition method.

In one embodiment, a method of using an electronic device (11) includes the application of a current in the resistive heating element (29) of one of the memory cells (M), which results in a change of crystalline phase of the layer made of the phase-change material (25) of the memory cell (M), allowing the storage of a data bit.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising:
a plurality of memory cells organized in an array of rows and columns, each memory cell including a stack of:
a resistive heating element;
a layer of phase-change material;
an upper electrode; and
a masking layer;
an encapsulation layer, wherein:
the layer of phase-change material, the upper electrode, and the masking layer are common to the memory cells of a same row and are covered by the encapsulation layer;
the encapsulation layer covers an upper surface of the masking layer and side flanks of the masking layer, side flanks of the upper electrode, and side flanks of the layer of phase-change material; and
the masking layer has a thickness lower than 15 nm.

2. The electronic device according to claim 1, wherein the masking layer has a thickness in the order of 5 nm.

3. The electronic device according to claim 1, wherein the masking layer is made of silicon nitride.

4. The electronic device according to claim 3, wherein the masking layer and the encapsulation layer are made of a silicon nitride having a same stoichiometry.

5. The electronic device according to claim 3, wherein the masking layer and the encapsulation layer have a density lower than 2.2 g/cm³.

6. The electronic device according to claim 3, wherein the masking layer or the encapsulation layer is made of a stack of a plurality of sub-layers.

7. The electronic device according to claim 1, wherein the masking layer and the encapsulation layer are crossed by a conductive via, the conductive via being in contact with the upper electrode.

8. The electronic device of claim 1, wherein each memory cell is configured to store a data bit by application of a current in the resistive heating element, resulting in a change of crystalline phase of the layer made of the phase-change material of the memory cell.

9. A method of manufacturing an electronic device including a plurality of memory cells organized in an array of rows and columns, the method comprising:
forming a stack including a resistive element, a layer of phase-change material, and an upper electrode;
depositing a masking layer on the stack with a thickness lower than 20 nm;
etching the masking layer and the stack to create lines in the layer of phase-change material, the upper electrode, and the masking layer; and
depositing an encapsulation layer covering an upper surface of the masking layer and side flanks of the masking layer, side flanks of the upper electrode, and side flanks of the layer made of the phase-change material.

10. The method according to claim 9, further comprising depositing the masking layer with a conformal deposition process.

11. The method according to claim 9, further comprising depositing the masking layer with a nanometric deposition process.

12. The method according to claim 9, further comprising depositing the masking layer with a pulsed plasma-enhanced chemical vapor deposition process.

13. The method according to claim 12, wherein the pulsed plasma-enhanced chemical vapor deposition process includes activating a plasma by pulses having a power in the range from 80 W to 200 W.

14. The method according to claim 12, wherein the plasma-enhanced chemical vapor deposition process has a duration longer than 30 seconds.

15. The method according to claim 12, wherein pulses of the plasma-enhanced chemical vapor deposition process have a frequency in the range from 800 Hz to 1,500 Hz.

16. The method according to claim 9, further comprising performing a step of thermal treatment of the masking layer after depositing the masking layer and before etching the masking layer.

17. The method according to claim 9, wherein the encapsulation layer and the masking layer are deposited according to the same deposition method.

18. A device, comprising:
a row of memory cells including a stack of:
a layer of phase change material;
an upper electrode; and
a masking layer, the layer of phase change material, the upper electrode, and the masking layer being common to all of the memory cells of the row, wherein each memory cell of the stack includes a respective resistive element coupled to the stack;
an encapsulation layer covering an upper surface of the masking layer and side flanks of the masking layer, the upper electrode, and the layer of phase-change material, wherein each memory cell of the row includes a respective resistive heating element.

19. The device of claim 18, wherein the masking layer has a thickness lower than 15 nm.

20. The device of claim 18, wherein the masking layer or the encapsulation layer is made of a stack of a plurality of sub-layers.
